(19) United States
(12) Patent Application Publication
(10) Pub. No.: US 2022/0320410 A1
(43) Pub. Date: Oct. 6, 2022

(54) THERMOELECTRIC CONVERSION ELEMENT AND MANUFACTURING METHOD THEREOF

(71) Applicant: TDK Corporation, Tokyo (JP)

(72) Inventors: Shota SUZUKI, Tokyo (JP); Youhei NODA, Tokyo (JP)

(21) Appl. No.: 17/640,213

(22) PCT Filed: Oct. 5, 2020
(86) PCT No.: PCT/JP2020/037721

§ 371 Date: Mar. 3, 2022

(30) Foreign Application Priority Data
Oct. 31, 2019 (JP) 2019-198813

(51) Int. Cl. H01L 35/32; H01L 37/04; H01L 35/34

(52) U.S. Cl. CPC H01L 35/32; H01L 37/04; H01L 35/34

(57) ABSTRACT

To obtain a high thermoelectromotive voltage with a simple structure in a thermoelectric conversion element with a magnetization direction, a temperature gradient direction, and an electromotive force direction mutually orthogonal. A thermoelectric conversion element 1 includes a tape-like member 10 including an insulating film and a thermoelectric material layer formed on the surface of the insulating film and having a magnetization direction, a temperature gradient direction, and an electromotive force direction which are mutually orthogonal and a pair of terminal electrodes E1 and E2 connected to the thermoelectric material layer at positions different in the longitudinal direction thereof. The tape-like member 10 is wound with the longitudinal direction thereof directed to the circumferential direction, and the thermoelectric material layer is radially magnetized. Thus, the radially magnetized tape-like thermoelectric material layer is circumferentially wound, so that a thermoelectromotive voltage can be generated in accordance with a temperature gradient in the axial direction. In addition, the electromotive force occurs circumferentially, making the structure of the tape-like member simple.

### TECHNICAL FIELD

The present invention relates to a thermoelectric conversion element and a manufacturing method thereof and, more particularly, to a thermoelectric conversion element with a magnetization direction, a temperature gradient direction, and an electromotive force direction mutually orthogonal and a thermoelectric conversion device having such a thermoelectric conversion element.

### BACKGROUND ART

Energy problems are big challenges facing humanity, and there has been strongly demanded a technology for converting energy existing in the environment into electric power. In particular, to achieve an IoT (Internet of Things) society, it is significantly necessary to ensure power supply sources for various devices. From this point of view, there is highly desired a technology that uses energy existing in the environment, such as a temperature gradient, as a power supply source. As a thermoelectric conversion element that generates power by using a temperature gradient, there are known one that uses a Seebeck effect and one that uses a Nernst effect.

The Nernst effect is a phenomenon in which, when a magnetic field is applied in a direction crossing (preferably, at right angle) a temperature gradient direction (heat flow direction) in a state where a temperature gradient is generated in a conductor, an electromotive force occurs in a direction orthogonal to both a temperature gradient direction and a magnetic field direction. The Nernst effect is said to be more efficient than the Seebeck effect theoretically. Actually, the fact that an Ettinghausen effect, which is a reverse process of the Nernst effect, achieves efficiency that exceeds the Peltier effect, which is a reverse process of the Seebeck effect, proves the high efficiency of the Nernst effect. However, a strong magnetic field is required to develop the Nernst effect, which is a large obstacle to practical use of a thermoelectric conversion element using the Nernst effect and to studies thereof.

Under such a circumstance, an anomalous Nernst effect (ANE) that uses not an external magnetic field, but anisotropic magnetization of a material now attracts attention. Although the anomalous Nernst effect is not necessarily uniformly defined, it is defined in the present specification as “a phenomenon in which, when a temperature gradient exists in a direction orthogonal to the magnetization direction of a magnetic body, an electromotive force occurs in a direction orthogonal to both the magnetization direction and temperature gradient direction”.

Patent Documents 1 and 2 disclose a thermoelectric conversion element using the anomalous Nernst effect. In the thermoelectric conversion element disclosed in Patent Documents 1 and 2, a plurality of linear patterns made of a thermoelectric material capable of developing the anomalous Nernst effect are arranged on the surface of an insulating layer and mutually connected in series by connection lines so as to accumulate an electromotive force generated in each of the linear patterns. Further, Patent Document 3 discloses a material with a high thermoelectromotive voltage capable of developing the anomalous Nernst effect.

### CITATION LIST

### Patent Document

[Patent Document 1] Japanese Patent No. 6079995
[Patent Document 2] JP 2018-078147A
[Patent Document 3] Pamphlet of WO 2019/009308
[Patent Document 4] Pamphlet of WO 2005/117154

### SUMMARY OF THE INVENTION

### Problem to be Solved by the Invention

However, the thermoelectric conversion elements disclosed in Patent Documents 1 and 2 are disadvantageously low in thermoelectromotive voltage. To increase the thermoelectromotive voltage, it is necessary to increase the total length of the linear patterns made of a thermoelectric material; however, it is difficult to increase the total length of the linear patterns per unit area with the structure described in Patent Documents 1 and 2.

Further, Patent Document 4 discloses a thermoelectric conversion element achieving a high thermoelectromotive voltage by winding a tape-like long sheet made of a thermoelectric material; however, the electromotive force direction of the thermoelectric conversion element described in Patent Document 4 is oriented in the axial direction, disadvantageously complicating the structure of the long sheet.

It is therefore an object of the present invention to provide a thermoelectric conversion element with a magnetization direction, a temperature gradient direction, and an electromotive force direction mutually orthogonal, capable of achieving a high thermoelectromotive voltage with a simple structure and a manufacturing method therefor.

### Means for Solving the Problem

A thermoelectric conversion element according to the present invention includes a tape-like member including an insulating film and a thermoelectric material layer formed on the surface of the insulating film and having a magnetization direction, a temperature gradient direction, and an electromotive force direction which are mutually orthogonal; and a pair of terminal electrodes connected to the thermoelectric material layer at positions different in the longitudinal direction thereof. The tape-like member is wound with the longitudinal direction thereof directed to the circumferential direction, and the thermoelectric material layer is radially magnetized.

According to the present invention, the radially magnetized tape-like thermoelectric material layer is circumferentially wound, so that a thermoelectromotive voltage can be generated in accordance with a temperature gradient in the axial direction. In addition, the electromotive force occurs circumferentially, allowing the structure of the tape-like member to be simple.

In the present invention, the degree of magnetization orientation in the radial direction of the thermoelectric material may be 80% or more. This makes it possible to obtain a higher thermoelectromotive voltage.

In the present invention, the tape-like member may further include a low heat conductivity layer covering the thermoelectric material layer and having a heat conductivity lower than that of the thermoelectric material layer. With this configuration, the thermoelectric material layer is sandwiched between the insulating film and the low heat conductivity layer, so that the thermoelectric material layer is protected, and most of a heat flow passes the thermoelectric material layer, allowing a higher thermoelectromotive voltage to be obtained. In this case, the heat conductivity of the low heat conductivity layer may be 0.8 times or less of that of the thermoelectric material layer. This allows an even higher thermoelectromotive voltage to be obtained.

The thermoelectric conversion element according to the present invention may further include a pair of heat equalizing members that axially sandwich the tape-like member and have a heat conductivity higher than that of the thermoelectric material layer. This reduces a temperature difference in a plane direction perpendicular to the axial direction to further equalize the in-plane distribution of the temperature gradient. In this case, the heat conductivity of the heat equalizing member may be 1.5 times or more of that of the thermoelectric material layer. This still further equalizes the in-plane distribution of the temperature gradient.

In the present invention, the thermoelectric material layer may be made of a material having a Weyl point in the vicinity of Fermi energy and exhibiting an anomalous Nernst effect. This makes it possible to obtain an even higher thermoelectromotive voltage.

A manufacturing method for a thermoelectric conversion element according to the present invention includes a step of producing a tape-like member by forming, on the surface of a long insulating film, a thermoelectric material layer with a magnetization direction, a temperature gradient direction, and an electromotive force direction mutually orthogonal, a step of magnetizing the thermoelectric material layer in the stacking direction by applying a magnetic field to the tape-like member, and a step of winding the tape-like member with the longitudinal direction thereof directed to the circumferential direction.

According to the present invention, it is possible to manufacture a thermoelectric conversion element having a high thermoelectromotive voltage with a simple method.

### Advantageous Effects of the Invention

As described above, according to the present invention, there can be provided a thermoelectric conversion element with a magnetization direction, a temperature gradient direction, and an electromotive force direction mutually orthogonal, capable of achieving a high thermoelectromotive voltage with a simple structure and a manufacturing method therefor.

### BRIEF DESCRIPTION OF THE DRAWINGS

FIG. 1 is a schematic perspective view illustrating the outer appearance of a thermoelectric conversion element 1 according to an embodiment of the present invention.

FIG. 2 is a schematic cross-sectional view taken along the line A-A in FIG. 1.

FIG. 3 is a schematic cross-sectional view taken along the circumferential direction of the tape-like member 10.

FIG. 4 is a schematic cross-sectional view taken along the circumferential direction of a tape-like member 10A according to a modification.

FIG. 5 is a table showing the configurations and electromotive forces of thermoelectric conversion elements of Examples 1 to 7.

### MODE FOR CARRYING OUT THE INVENTION

Hereinafter, preferred embodiments of the present invention will be described in detail with reference to the accompanying drawings.

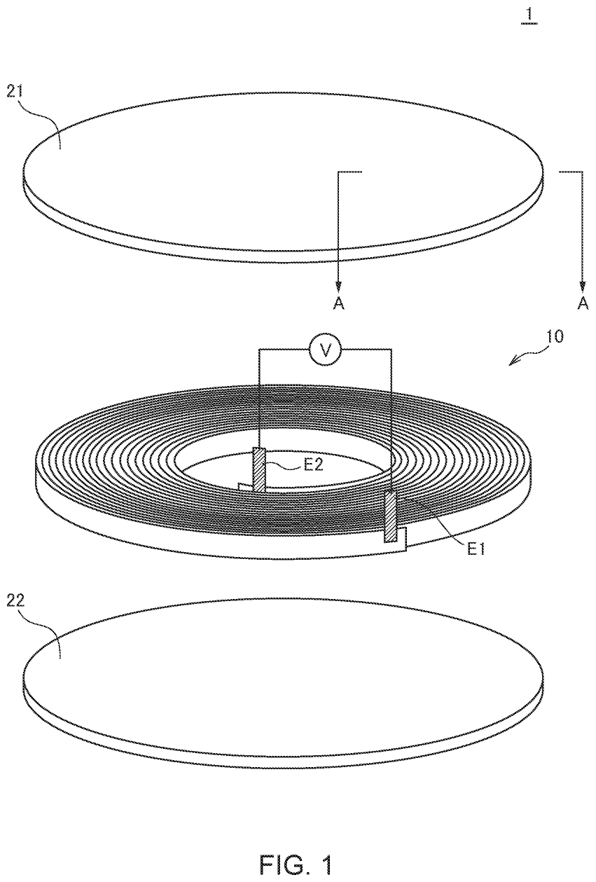

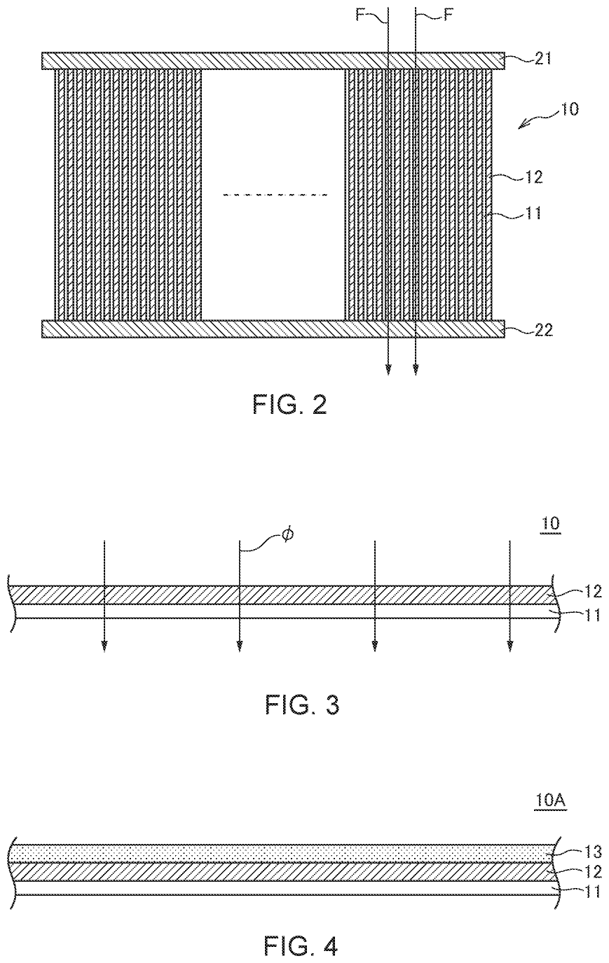

FIG. 1 is a schematic perspective view illustrating the outer appearance of a thermoelectric conversion element 1 according to an embodiment of the present invention. FIG. 2 is a schematic cross-sectional view taken along the line A-A in FIG. 1.

The thermoelectric conversion element 1 according to the present embodiment is an element that generates a thermoelectromotive voltage based on a temperature gradient and includes, as illustrated in FIGS. 1 and 2, a spirally wound tape-like member 10, heat equalizing members 21 and 22 sandwiching the tape-like member 10 from both sides in the axial direction, and terminal electrodes E1 and E2 at which a thermoelectromotive voltage appears. The thermoelectric conversion element 1 according to the present embodiment is not particularly limited in application and may be applied to a micro generator device that uses a temperature gradient to generate power or to a heat flow sensor that detects a slight heat flow.

FIG. 3 is a schematic cross-sectional view taken along the circumferential direction of the tape-like member 10.

As illustrated in FIG. 3, the tape-like member 10 is a long member constituted by an insulating film 11 and a thermoelectric material layer 12 formed on the surface of the insulating film 11 and is spirally wound in a plurality of turns with the longitudinal direction thereof directed to the circumferential direction. The material of the insulating film 11 is not particularly limited as long as it has an insulating property and may be PET resin. Further, the thickness (radial thickness) of the insulating film 11 is preferably as small as possible in a range where a sufficient mechanical strength is maintained. The heat conductivity of the insulating film 11 is preferably lower than that of the thermoelectric material layer 12.

As a thermoelectric material of the thermoelectric material layer 12, it is not particularly limited in type as long as a magnetization direction, a temperature gradient direction, and an electromotive force direction thereof are mutually orthogonal and may be a material (Co₂MnGa, Mn₃Sn, FePt, etc.) having the anomalous Nernst effect or may be a material (YIG/Pt, etc.) having a spin Seebeck effect. Of the materials having the anomalous Nernst effect, FePt has a thermoelectric coefficient of about 1 μV/K, and Co₂MnGa has a thermoelectric coefficient of about 7 μV/K. In particular, when a material having a Weyl point in the vicinity of Fermi energy is used as a material having the anomalous Nernst effect, a larger electromotive force can be obtained.

When the thermoelectric material constituting the thermoelectric material layer 12 has the anomalous Nernst effect, a voltage V to be obtained by a temperature gradient ΔT/t is defined as V=S_{N}ΔT (l/t), where “S_{N}” is a Nernst coefficient, “l” is the length of the thermoelectric material in the electromotive force direction, and “t” is the thickness of the thermoelectric material in the temperature gradient direction. Thus, a higher voltage V can be obtained by increasing the length l of the thermoelectric material in the electromotive force direction or reducing the thickness t of the thermoelectric material in the temperature gradient direction. However, the reduction in the thickness of the thermoelectric material in the temperature gradient direction correspondingly reduces a temperature difference ΔT, making it difficult to increase the voltage V by reducing the thickness t of the thermoelectric material in the temperature gradient direction. As a result, it is necessary to increase the length l of the thermoelectric material in the electromotive force direction in order to increase the voltage V.

However, when the length l of the thermoelectric material in the electromotive force direction is linearly increased, the size of the thermoelectric conversion element is disadvantageously increased. Thus, in the thermoelectric conversion element 1 according to the present embodiment, the thermoelectric material is not linearly increased in length, but the long tape-like member 10 is spirally wound in a plurality of turns. This makes it possible to sufficiently increase the length l of the thermoelectric material in the electromotive force direction while suppressing increase in the planar size. In the present embodiment, the magnetization direction of the thermoelectric material layer 12 is radial, and an electromotive force circumferentially occurs in accordance with the temperature gradient in the axial direction. The radial magnetization of the thermoelectric material layer 12 can be achieved by applying, in the thickness direction, a magnetic field ϕ to the tape-like member 10 before being wound, as illustrated in FIG. 3. Thus, the thermoelectric material layer 12 can be radially magnetized with a simple method. Alternatively, in place of applying a magnetic field to the tape-like member 10 before being wound, magnetization may be carried out with the inner diameter area of the wound tape-like member 10 set to the N pole (or S pole) and the radial outer circumferential area of the wound tape-like member 10 set to the S pole (or N pole). Although the thermoelectric material layer 12 need not necessarily be completely magnetized in the radial direction, the degree of magnetization orientation in the radial direction is preferably 80% or more.

The thermoelectric material layer 12 located in the vicinity of the outer circumferential end of the tape-like member 10 is connected to the terminal electrode E1, and the thermoelectric material layer 12 located in the vicinity of the inner circumferential end of the tape-like member 10 is connected to the terminal electrode E2. Thus, when a temperature gradient exists in the axial direction, an electromotive force occurs circumferentially in the spirally wound thermoelectric material layer 12. Since the thermoelectric conversion element 1 according to the present embodiment has a structure in which the long and thin tape-like member 10 is wound, it is possible to significantly increase the length l of the thermoelectric material in the electromotive force direction (circumferential direction) while suppressing increase in the planar size. In addition, when the heat conductivity of the thermoelectric material layer 12 is higher than that of the insulating film 11, most of an axial heat flow F passes the thermoelectric material layer 12, so that a voltage V higher than that in a conventional thermoelectric conversion element appears between the terminal electrodes E1 and E2.

The heat equalizing members 21 and 22 reduce a temperature difference in a plane direction perpendicular to the axial direction to further equalize the in-plane distribution of the temperature gradient to be applied to the tape-like member 10. As the material of the heat equalizing members 21 and 22, a material having a higher heat conductivity than the thermoelectric material layer 12 is preferably used. More preferably, a material having a heat conductivity 1.5 or more times higher than that of the thermoelectric material layer 12 is used. The heat conductivity of the thermoelectric material layer 12 differs depending on the thermoelectric material to be used and is about 1 W/mK to 100 W/mK. For example, the heat conductivity of FePt is about 10 W/mK.

FIG. 4 is a schematic cross-sectional view taken along the circumferential direction of a tape-like member 10A according to a modification.

The tape-like member 10A according to the modification illustrated in FIG. 4 differs from the tape-like member 10 illustrated in FIG. 3 in that it further has a low heat conductivity layer 13 that covers the thermoelectric material layer 12. That is, in the tape-like member 10A according to the modification illustrated in FIG. 4, the thermoelectric material layer 12 is sandwiched between the insulating film 11 and the low heat conductivity layer 13 in the radial direction. The low heat conductivity layer 13 is made of a material having a heat conductivity lower than that of the thermoelectric material layer 12. Preferably, the heat conductivity of the low heat conductivity layer 13 is 0.8 times or less of that of the thermoelectric material layer 12. When the tape-like member 10A having the thus configured low heat conductivity layer 13 is used, the thermoelectric material layer 12 is sandwiched between the insulating film 11 and the low heat conductivity layer 13, so that the thermoelectric material layer 12 is protected, and most of a heat flow passes the thermoelectric material layer 12, allowing a higher thermoelectromotive voltage to be obtained.

As described above, the thermoelectric conversion element 1 according to the present embodiment has a configuration in which the long and thin tape-like member 10 (or 10A) is wound in a plurality of turns, so that it is possible to increase the voltage V in accordance with the temperature gradient in the axial direction while suppressing increase in the planar size in a direction perpendicular to the axial direction. In addition, the tape-like member 10 can be easily manufactured by applying a magnetic field to the thermoelectric material layer 12 formed on the surface of the long insulating film 11 to magnetize the thermoelectric material layer 12 in the stacking direction, followed by winding with the longitudinal direction thereof directed to the circumferential direction, thereby suppressing manufacturing cost.

While the preferred embodiment of the present invention has been described, the present invention is not limited to the above embodiment, and various modifications may be made within the scope of the present invention, and all such modifications are included in the present invention.

### EXAMPLES

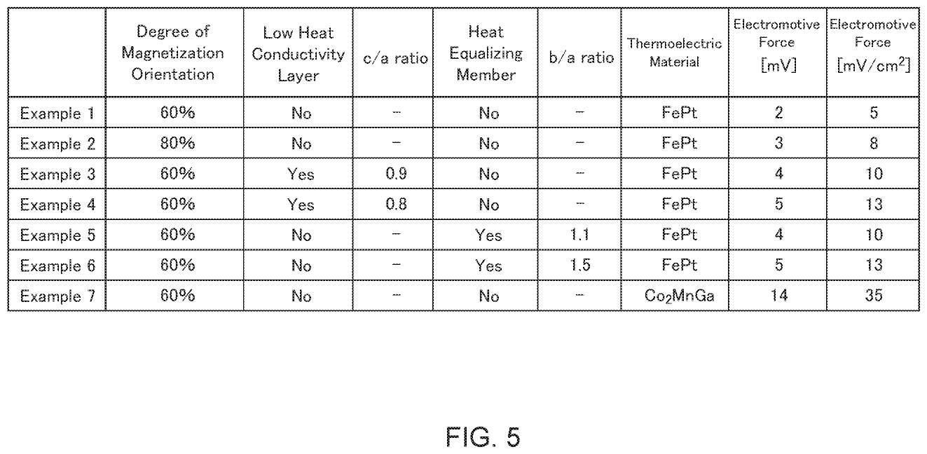

FIG. 5 is a table showing the configurations and electromotive forces of thermoelectric conversion elements of Examples 1 to 7.

### Example 1

A tape-like member was produced by forming a thermoelectric material layer made of FePt and having a thickness of 0.1 μm on an insulating film made of polyethylene terephthalate and having a thickness of 5 μm, a width of 5 mm, and a length of 2.3 m. Then, a magnetic field was applied to the tape-like member in the thickness direction thereof to magnetize the thermoelectric material layer in the thickness direction, followed by winding of the tape-like member with the longitudinal, thickness, and width directions thereof directed respectively to the circumferential, radial, and axial directions thereof, whereby a thermoelectric conversion element of Example 1 was produced. The outer diameter of the wound tape-like member was 7.1 mm. Thus, the occupied area of the tape-like member in a plane perpendicular to the axial direction was 0.4 cm². The heat conductivity of the thermoelectric material layer was 10 W/mK, and the heat conductivity of the insulating film was 0.3 W/mK. The degree of magnetization orientation in the radial direction of the thermoelectric material was 60%. An axial temperature difference of 10° C. was applied to the thus configured thermoelectric conversion element of Example 1, and voltage appearing between the thermoelectric material layers positioned at the outer and inner circumferential ends was measured. As a result, obtained voltage was 2 mV, and voltage per unit area was 5 mV/cm².

### Example 2

There was produced a thermoelectric conversion element of Example 2 having the same structure as that of Example 1 except that the degree of magnetization orientation in the radial direction of the thermoelectric material layer was increased to 80%, and voltage was measured in the same conditions. As a result, obtained voltage was 3 mV, and voltage per unit area was 8 mV/cm², which were higher than those obtained in Example 1.

### Example 3

There was produced a thermoelectric conversion element of Example 3 having the same structure as that of Example 1 except that a low heat conductivity layer having a thickness of 0.01 μm was formed on the surface of the thermoelectric material layer, and voltage was measured in the same conditions. The heat conductivity of the low heat conductivity layer was 9 W/mK. A c/a ratio (a is the heat conductivity of the thermoelectric material layer, and b is the heat conductivity of the low heat conductivity layer) was 0.9. As a result, obtained voltage was 4 mV, and voltage per unit area was 10 mV/cm², which were higher than those obtained in Example 1.

### Example 4

There was produced a thermoelectric conversion element of Example 4 having the same structure as that of Example 3 except that a material having a heat conductivity of 8 W/mK was used for the low heat conductivity layer, and voltage was measured in the same conditions. The c/a ratio was 0.8. As a result, obtained voltage was 5 mV, and voltage per unit area was 13 mV/cm², which were higher than those obtained in Example 3.

### Example 5

There was produced a thermoelectric conversion element of Example 5 having the same structure as that of Example 1 except that a pair of heat equalizing members of 1 mm thickness were additionally provided so as to axially sandwich the tape-like member, and voltage was measured in the same conditions. The heat conductivity of the heat equalizing member was 11 W/mK. A b/a ratio (a is the heat conductivity of the thermoelectric material layer, and b is the heat conductivity of the heat equalizing layer) was 1.1. As a result, obtained voltage was 4 mV, and voltage per unit area was 10 mV/cm², which were higher than those obtained in Example 1.

### Example 6

There was produced a thermoelectric conversion element of Example 6 having the same structure as that of Example 5 except that a material having a heat conductivity of 15 W/mK was used for the heat equalizing member, and voltage was measured in the same conditions. The b/a ratio was 1.5. As a result, obtained voltage was 5 mV, and voltage per unit area was 13 mV/cm², which were higher than those obtained in Example 5.

### Example 7

There was produced a thermoelectric conversion element of Example 7 having the same structure as that of Example 1 except that Co₂MnGa was used for the thermoelectric material, and voltage was measured in the same conditions. As a result, obtained voltage was 14 mV, and voltage per unit area was 35 mV/cm², which were higher than those obtained in Example 1.

### REFERENCE SIGNS LIST

1, 2 thermoelectric conversion element
10, 10A tape-like member
11 insulating film
12 thermoelectric material layer
13 low heat conductivity layer
21, 22 heat equalizing member
E1, E2 terminal electrode
F heat flow
ϕ magnetic field

1. A thermoelectric conversion element comprising:
a tape-like member including an insulating film and a thermoelectric material layer formed on a surface of the insulating film and having a magnetization direction, a temperature gradient direction, and an electromotive force direction which are mutually orthogonal; and
a pair of terminal electrodes connected to the thermoelectric material layer at positions different in a longitudinal direction thereof,
wherein the tape-like member is wound such that the longitudinal direction is directed to a circumferential direction, and
wherein the thermoelectric material layer is radially magnetized.

2. The thermoelectric conversion element as claimed in claim 1, wherein a degree of magnetization orientation in a radial direction of the thermoelectric material is 80% or more.

3. The thermoelectric conversion element as claimed in claim 1, wherein the tape-like member further includes a low heat conductivity layer covering the thermoelectric material layer and having a heat conductivity lower than that of the thermoelectric material layer.

4. The thermoelectric conversion element as claimed in claim 3, wherein the heat conductivity of the low heat conductivity layer is 0.8 times or less of that of the thermoelectric material layer.

5. The thermoelectric conversion element as claimed in claim 1, further comprising a pair of heat equalizing members that axially sandwich the tape-like member and have a heat conductivity higher than that of the thermoelectric material layer.

6. The thermoelectric conversion element as claimed in claim 5, wherein the heat conductivity of the heat equalizing member is 1.5 times or more of that of the thermoelectric material layer.

7. The thermoelectric conversion element as claimed in claim 1, wherein the thermoelectric material layer is made of a material having a Weyl point in a vicinity of Fermi energy and exhibiting an anomalous Nernst effect.

8. A method for manufacturing a thermoelectric conversion element, the method comprising:
a step of producing a tape-like member by forming, on a surface of a long insulating film, a thermoelectric material layer with a magnetization direction, a temperature gradient direction, and an electromotive force direction mutually orthogonal;
a step of magnetizing the thermoelectric material layer in a stacking direction by applying a magnetic field to the tape-like member; and
a step of winding the tape-like member such that a longitudinal direction is directed to a circumferential direction.

9. The thermoelectric conversion element as claimed in claim 2, wherein the tape-like member further includes a low heat conductivity layer covering the thermoelectric material layer and having a heat conductivity lower than that of the thermoelectric material layer.
